(19) United States
(12) Patent Application Publication
(10) Pub. No.: US 2014/0038329 A1
(43) Pub. Date: Feb. 6, 2014

(54) EPITAXIAL GROWTH ON THIN LAMINA

(71) Applicant: GTAT Corporation, Nashua, NH (US)

(72) Inventor: Christopher J. Petti, Mountain View, CA (US)

(73) Assignee: GTAT Corporation, Nashua, NH (US)

(21) Appl. No.: 13/957,397

(22) Filed: Aug. 1, 2013

Related U.S. Application Data
(60) Provisional application No. 61/678,758, filed on Aug. 2, 2012.
(60) Provisional application No. 61/702,656, filed on Sep. 18, 2012.

(51) Int. Cl. H01L 21/762; H01L 33/00; H01L 31/18

(52) U.S. Cl. CPC H01L 21/76254; H01L 31/18; H01L 33/005
USPC 438/33; 438/460; 438/68

(57) ABSTRACT

Methods and apparatus are provided for forming an electronic device from a lamina and an epitaxially grown semiconductor material. The method includes providing a donor body comprising a top surface, epitaxially growing a semiconductor material on the top surface and implanting the top surface of the donor body with an ion dosage to form a cleave plane. After implantation, a lamina may be exfoliated from the donor body, wherein the top surface of the donor body becomes a first surface of the lamina. Exfoliating the lamina forms a second surface of the lamina, wherein the first surface is opposite the second surface. A metal support may be constructed on the lamina.

### BACKGROUND OF THE INVENTION

Sivaram et al., U.S. patent application Ser. No. 12/026,530, “Method to Form a Photovoltaic Cell Comprising a Thin Lamina,” filed Feb. 5, 2008, owned by the assignee of the present invention and hereby incorporated by reference, describes fabrication of a photovoltaic cell comprising a thin semiconductor lamina formed of non-deposited semiconductor material. Using the methods of Sivaram et al., photovoltaic cells, rather than being formed from sliced wafers, are formed of thin semiconductor laminae without wasting silicon through kerf loss or by fabrication of an unnecessarily thick cell, thus reducing cost. The same donor wafer can be reused to form multiple laminae, further reducing cost, and may be resold after exfoliation of multiple laminae for some other use.

Referring to FIG. 1A, in embodiments of Sivaram et al., a semiconductor donor wafer 20 is implanted through first surface 10 with one or more species of gas ions, for example hydrogen and/or helium ions. The implanted ions define a cleave plane 30 within the semiconductor donor wafer. As shown in FIG. 1B, donor wafer 20 is affixed at a first surface 10 to receiver 60. Cleaving is most easily achieved by heating, for example to temperatures of 500 degrees C. or more. Referring to FIG. 1C, lamina 40 is heated and cleaves, or exfoliates, from donor wafer 20 at cleave plane 30, creating second surface 62. It has been found that the step of implanting to define the cleave plane may cause damage to the crystalline lattice of the monocrystalline donor wafer. This damage, if unrepaired, may impair cell efficiency. A relatively high-temperature anneal, for example at 900 degrees C., 950 degrees C., or more, will repair most implant damage in the body of the lamina.

In embodiments of Sivaram et al., additional processing before and after the cleaving step forms a photovoltaic cell comprising semiconductor lamina 40, which is between about 0.2 and about 100 microns thick. In other embodiments of Sivaram et al., lamina 40 may be, for example, between about 0.2-50 microns thick, between about 1-20 microns thick, between about 1-10 microns thick, between about 4-20 microns thick, or between about 5-15 microns thick, though any thickness within the named range is possible. FIG. 1D shows the structure inverted, with receiver 60 at the bottom, as during operation in some embodiments of Sivaram. Receiver 60 may be a discrete receiver element having a maximum width no more than 50 percent greater than that of donor wafer 20, and preferably about the same width, as described in Herner, U.S. patent application Ser. No. 12/057,265, “Method to Form a Photovoltaic Cell Comprising a Thin Lamina Bonded to a Discrete Receiver Element,” filed on Mar. 27, 2008, owned by the assignee of the present application and hereby incorporated by reference. Alternatively, a plurality of donor wafers may be affixed to a single, larger receiver, and a lamina cleaved from each donor wafer.

In summary, the primary stages of producing a lamina are ion implantation, exfoliation (cleaving the lamina from the donor wafer), and annealing (to repair defects in the lamina).

### SUMMARY OF THE INVENTION

Methods and apparatus are provided for forming an electronic device from a thin lamina and an epitaxially grown semiconductor material. The method may comprise providing a donor body comprising a top surface, epitaxially growing a semiconductor material on the top surface and implanting the top surface of the donor body with an ion dosage to form a cleave plane. After implantation, a lamina may be exfoliated from the donor body, wherein the top surface of the donor body becomes a first surface of the lamina, and the step of exfoliating the lamina forms a second surface of the lamina wherein the first surface is opposite the second surface. A metal support may be constructed on the lamina after the lamina is exfoliated from the donor body. A layer of epitaxially grown material may be disposed on the first surface of the lamina at any point in the process such as before the step of ion implantation.

### BRIEF DESCRIPTION OF DRAWINGS

FIGS. 1A-1D are cross-sectional views showing stages in formation of the photovoltaic device of Sivaram et al., U.S. patent application Ser. No. 12/026,530.

FIG. 2 is a simplified exemplary flow chart of device fabrication.

FIG. 3 is a simplified exemplary flow chart of device fabrication.

FIGS. 4A and 4B show schematic views of exemplary devices of this invention.

FIG. 5 shows a schematic view of an embodiment of a device of this invention.

### DETAILED DESCRIPTION OF THE EMBODIMENTS

Methods and apparatus are provided for forming an electronic device from a thin lamina and an epitaxially grown semiconductor material. The method may comprise providing a donor body comprising a top surface, epitaxially growing a semiconductor material on the top surface and implanting the top surface of the donor body with an ion dosage to form a cleave plane. After implantation, a lamina/epitaxial layer assembly may be exfoliated from the donor body, wherein the top surface of the donor body becomes a first surface of the lamina and the step of exfoliating the lamina forms a second surface of the lamina, wherein the first surface is opposite the second surface, and wherein the lamina is between 2 and 40 microns thick between the first surface and the second surface. The lamina/epitaxial layer assembly may be between 3 and 50 microns thick. A metal support may be constructed on the lamina/epitaxial layer assembly.

Thinner laminas formed from silicon donor bodies may be used to form electronic devices by permanent fixation of the lamina to support elements. Thin lamina from semiconductor materials other than silicon may be used to form a wide variety of electronic devices such as photovoltaic (PV) devices, light emitting devices (LEDs), high electron mobility transistors (HEMTs), high-power Schottky diodes, high-power diffused metal-oxide-semiconductor field-effect transistors (DMOSFETS), or terahertz (Thz) optoelectronic elements. Typically, lamina formed in this manner must incorporate the support element into any resultant device. In the present invention, methods and apparatus are described in which a donor body may be used to grow epitaxial layers and a thin, free standing lamina including the epitaxial layers may be formed and separated from a donor body without prior permanent bonding to a support element. In the present invention a donor body is used as a support for the growth of an epitaxial layer and is implanted through a first surface to form a cleave plane. The first surface of a donor body or epitaxial layer may then be separably contacted to a support element. A heating step is performed that exfoliates a lamina from the first surface donor body, creating a second surface. This process occurs in the absence of bonded support element on the lamina. The ion implantation and exfoliation conditions may have a significant effect on the quality of the lamina produced by this method and may be optimized to reduce the amount of physical defects that may be formed in the free standing lamina. A permanent metal support or other layers may then be constructed on either side of the lamina.

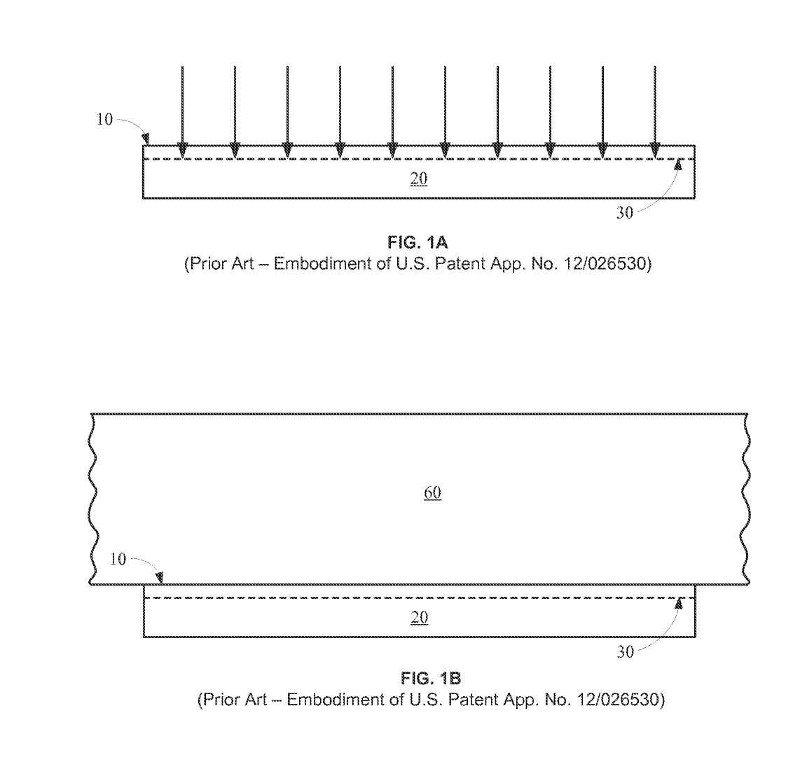

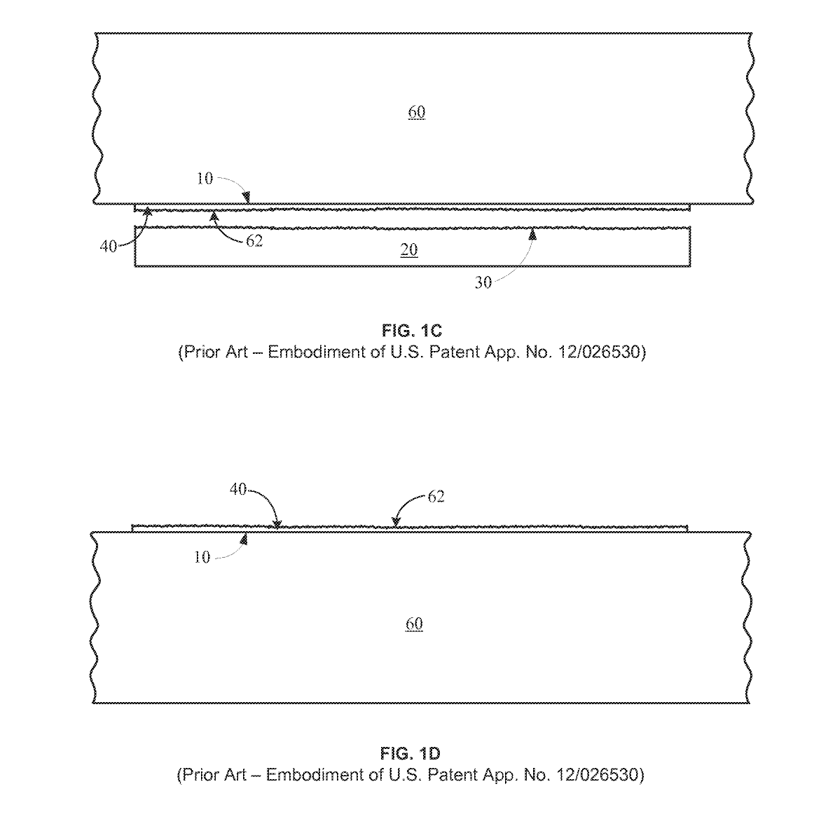

Sivaram et al., U.S. patent application Ser. No. 12/026,530, “Method to Form a Photovoltaic Cell Comprising a Thin Lamina,” filed Feb. 5, 2008, owned by the assignee of the present invention and hereby incorporated by reference, describes the fabrication of a photovoltaic cell comprising a thin semiconductor lamina formed of non-deposited semiconductor material. Referring to FIG. 1A, in embodiments of Sivaram et al., a semiconductor donor body 20 is implanted through first surface 10 with one or more species of gas ions, for example hydrogen and/or helium ions. The implanted ions define a cleave plane 30 within the semiconductor donor body. As shown in FIG. 1B, donor body 20 is affixed at first surface 10 to receiver 60. Referring to FIG. 1C, an anneal step causes lamina 40 to cleave from donor body 20 at cleave plane 30, creating second surface 62. In embodiments of Sivaram et al., additional processing before and after the cleaving step forms a photovoltaic cell comprising semiconductor lamina 40, which is between about 0.2 and about 100 microns thick, for example between about 0.2 and about 50 microns, for example between about 1 and about 20 microns thick, in some embodiments between about 1 and about 10 microns thick or between about 4 and about 20 or between about 5 and about 15 microns thick, though any thickness within the named range is possible. FIG. 1D shows the structure inverted, with receiver 60 at the bottom, as during operation in some embodiments. Receiver 60 may be a discrete receiver element having a maximum width no more than 50 percent greater than that of donor body 10, and preferably about the same width, as described in Herner, U.S. patent application Ser. No. 12/057,265, “Method to Form a Photovoltaic Cell Comprising a Thin Lamina Bonded to a Discrete Receiver Element,” filed on March 27, 2008, owned by the assignee of the present application and hereby incorporated by reference. Alternatively, a plurality of donor bodies may be affixed to a single, larger receiver, and a lamina cleaved from each donor body. Using the methods of Sivaram et al., electronic devices, rather than being formed from sliced wafers, are formed of thin semiconductor laminae without wasting silicon through kerf loss or by fabrication of an unnecessarily thick cell, thus reducing cost. The same donor wafer can be reused to form multiple laminae, further reducing cost, and may be resold after exfoliation of multiple laminae for some other use.

In the present invention, a free standing lamina with one or more epitaxially grown layers is formed by implanting a semiconductor donor body with ions to define a cleave plane before or after epitaxial growth and exfoliating a semiconductor lamina from the donor body at the cleave plane. The lamina has a non-bonded first surface and a non-bonded second surface opposite the first. After the exfoliation step, the lamina is separated from the donor body and fabricated into an electronic device of which the lamina and the epitaxial layer comprise a portion. The combined thickness of the lamina and epitaxial layer may be between about 2 microns and about 25 microns such as between 15 and 25 microns. One, two or more additional layers may be formed on the either surface of the lamina/epitaxial layer assembly before incorporating the lamina into an electronic device. The thickness of lamina is determined by the depth of cleave plane. In many embodiments, the thickness of lamina is between about 1 and about 30 microns, for example between about 2 and about 5 microns, for example about 4.5 microns. In other embodiments, the thickness of lamina is between about 4 and about 20 microns, for example between about 10 and about 15 microns, for example about 11 microns. The second surface is created by cleaving. While different flows are possible, in general, the lamina/epitaxial layer assembly is provided without permanent or adhesive fixing to a support element. In most embodiments, it has been exfoliated and separated from a larger donor body, such as a wafer or boule.

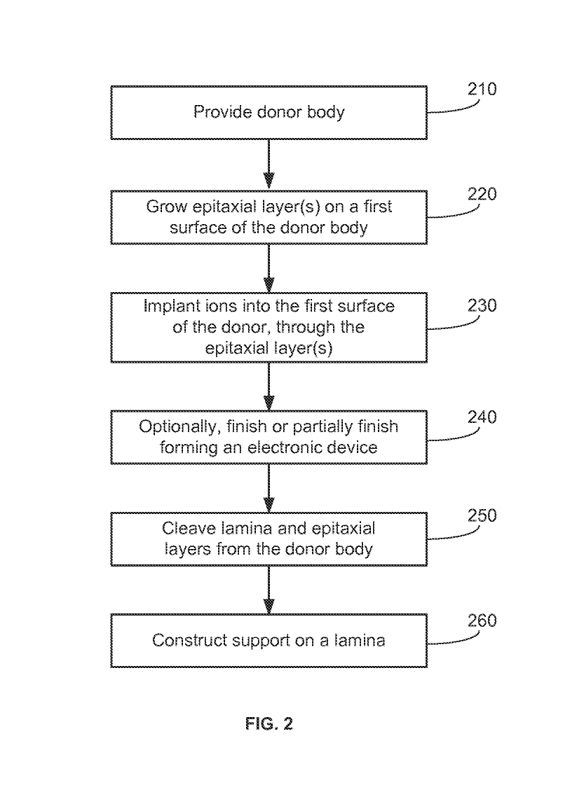

Turning to FIG. 2 in which an embodiment of the present invention is outlined, a donor body is first prepared as a surface for epitaxial growth of a semiconductor material (step 1). The donor body may be any semiconductor material such as germanium, gallium arsenide, silicon carbide, silicon, gallium nitride or the like. One or more layers may be epitaxially grown on the first (e.g., top) surface of the donor body (step 2). Materials that may be epitaxially grown include GaN, AlGaN, AN, Ge, Ga(In)As, GaInP, AlGaInP, AlInP, InGaN, SiC, GaAs, or the like. In some embodiments, this epitaxial layer may be doped as either n-type or p-type while it is being grown. In some embodiments, the implantation of ions in the donor body occurs after the epitaxial growth of one or more layers is complete (step 3). In some embodiments the implant temperature may be maintained between 25 and 300° C., such as between 100 and 200° C. or between 120 and 180° C. One aspect of the invention is that the implant temperature may be adjusted depending upon the material and orientation of the donor body or epitaxial layers. In some embodiments, the material is silicon carbide and the implant temperature may be between 70 and 350° C. The implant temperature may be optimized for any material or orientation and implant energy. Other implantation conditions that may be adjusted may include initial process parameters such as implant dose and the ratio of implanted ions (e.g., H:He ratio). In some embodiments implant conditions may be optimized in combination with exfoliation conditions such as exfoliation temperature, exfoliation susceptor vacuum level, heating rate and/or exfoliation pressure in order to maximize the area that is substantially free of physical defects present in the lamina. In some embodiments, greater than 90% of the surface area of the lamina produced by methods of this invention is free from physical defects. After the implantation to form a cleave plane, the donor body/epitaxial layers may be contacted with additional layers or components in order to complete or partially complete an electronic device (step 4).

Following the implantation to form a cleave plane, the donor body may be contacted to a temporary support element such as a susceptor assembly and a lamina/epitaxial layer assembly may be cleaved from the donor body (step 5). Typically donor bodies, lamina or electronic devices in various stages of manufacture may be affixed to temporary or permanent carriers with adhesive or via chemical bonding. When adhesive is used, additional steps are required to initiate the debonding of the lamina and/or to clean the surface of the photovoltaic cell and the temporary carrier after detachment. Alternatively, support elements may be dissolved or otherwise removed and rendered unusable for further support steps. In one aspect of this invention, the donor body/epitaxial layer(s) are separably contacted, without adhesive or permanent bonding, with a support element such as a susceptor assembly in order to stabilize the lamina during exfoliation. The contact may be direct contact between the donor body and support element, and comprise no adherents or bonding steps that require a chemical or physical step to disrupt the contact beyond merely lifting the donor body or lamina from the susceptor. The susceptor may then be reused as a support element without further processing. In some embodiments of methods of this invention, the implanted donor body may be separably contacted with a support element such as a susceptor assembly wherein the interacting force between the donor body and the susceptor during exfoliation is solely the weight of the donor body on the susceptor or solely the weight of the susceptor assembly on the donor body. In the case in which contact is established solely by the weight of the donor body, the donor body may be oriented with the implanted side facing down and in contact with the susceptor. Alternatively, the donor body may be oriented with the implanted side facing up and not in contact with the susceptor. In this case, a cover plate may be used to stabilize the lamina during and after exfoliation. In other embodiments the contacting may further comprise a vacuum force between the susceptor and the donor body. A vacuum force may be applied to the donor body in order to temporarily fix the donor body to a susceptor assembly without the use of adhesives, chemical reactions, electrostatic pressure or the like.

Contacting the lamina to a non-bonded support element during the steps of exfoliation and damage anneal, as in the present invention, provides several significant advantages. The steps of exfoliation and anneal take place at relatively high temperature. If a pre-formed support element is affixed, such as with adhesives or chemicals, to the donor body before these high-temperature steps, it will necessarily be exposed to high temperature along with the lamina, as will any intervening layers. Many materials cannot readily tolerate high temperature, and if the coefficients of thermal expansion (CTEs) of the support element and the lamina are mismatched, heating and cooling will cause strain which may damage the thin lamina. Thus, a non-bonded support element provides for an optimized surface for lamina manufacture independent of bonding and debonding protocols that would potentially inhibit the formation of a defect free lamina. The method of this invention beneficially provides for the construction of additional layers to either side of the lamina/epitaxial assembly.

Following the contacting of the donor body to the susceptor assembly, heat may be applied to the donor body to cleave a lamina from the donor body at the cleave plane. Exfoliation conditions may be optimized to cleave the lamina from the donor body in order to minimize physical defects in a lamina exfoliated in the absence of an adhered support element. The exfoliated lamina may be separated from the donor body by any such as by applying a deforming force to a first surface of the donor body away from an opposite surface of the newly formed lamina. A metal support may be constructed (step 6 of FIG. 2) on either side of the lamina/epitaxial layer assembly. The separated lamina/epitaxial layer assembly may remain on the susceptor plate or be transferred to a different temporary or permanent support element for further processing. In some embodiments a permanent support may be constructed on the free standing lamina/epitaxial layer assembly.

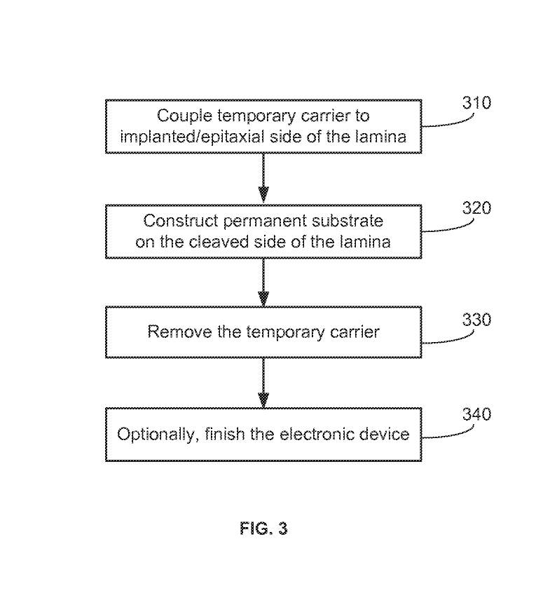

In some embodiments an electronic device may be constructed by the method outlined in FIG. 3 wherein a temporary carrier is contacted to the epitaxial side of the lamina/epitaxial layer assembly (step 1) and a permanent substrate is constructed on the cleaved side of the lamina (step 2). The permanent substrate may be, for example, metal sputtered or electroplated directly onto the lamina or any intervening layers. The permanent substrate may be a metal such as a flexible metal. In some embodiments the coefficient of thermal expansion (CTE) of the metal substrate may be matched or nearly matched (e.g., within 10%) of the CTE of the lamina between a defined temperature range, such as between 300 and 1000° C. or between 600 and 900° C. or between 300 and 600° C. After the construction of the metal substrate, the temporary carrier may be removed (step 3) and an electronic device may be optionally fabricated (step 4).

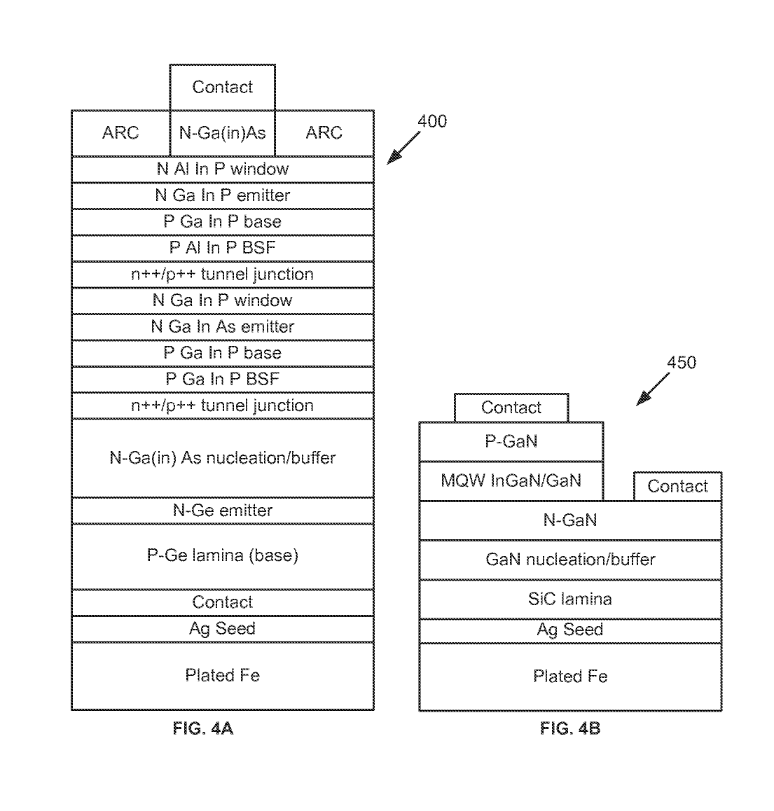

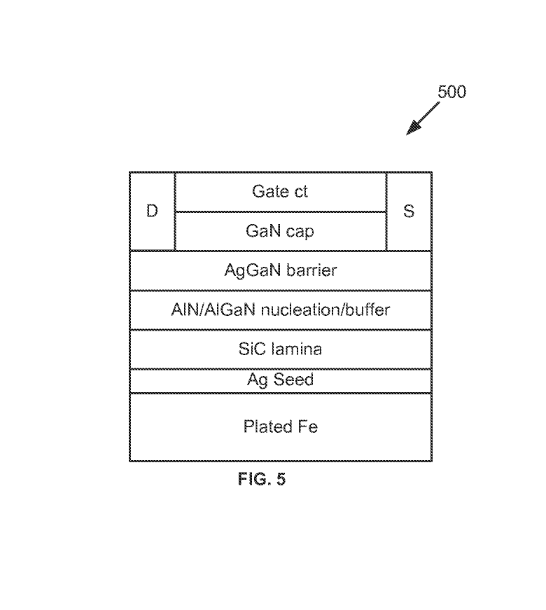

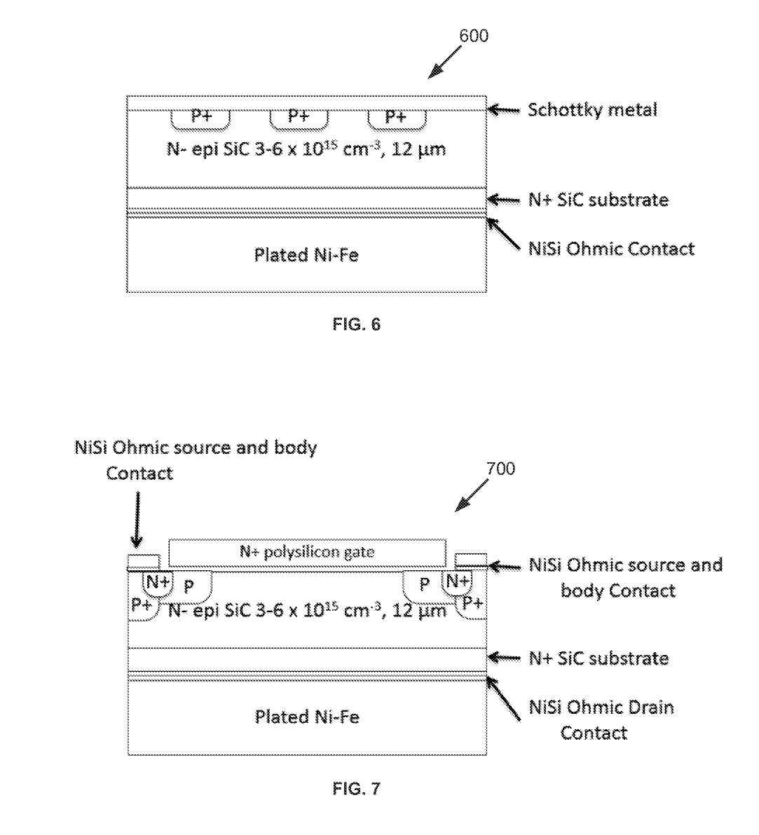

Any number of electronic devices may be fabricated by the methods of this invention as shown in FIGS. 4 and 5. In some embodiments a triple junction PV cell may be fabricated with lamina such as a germanium lamina (FIG. 4A). In some embodiments an LED may be fabricated by methods of this invention with a gallium nitride lamina (FIG. 4B). Solid-state power devices—used in switching or amplifying large voltages and currents—are important components in communications, power delivery, and, increasingly, transportation applications. These devices may also be constructed by methods of this invention. One of the biggest innovations in this field in the last 10 years has been the introduction of high electron mobility transistors (HEMTs) made on III-V semiconductors such as gallium nitride (GaN). These devices can be used at higher frequencies, control larger voltages in smaller areas, and dissipate (that is, waste) less power than similar transistors made with silicon. However, manufacturing GaN HEMTs presents some of the same challenges found in GaN LEDs: GaN is difficult and expensive to grow in bulk, so it is usually formed via heteroepitaxy on other substrates: sapphire, SiC, or silicon. For HEMTs, sapphire is less desirable because of its poor thermal conductivity. Silicon carbide (SiC) has excellent thermal conductivity, but it is expensive. Silicon is cheaper and compatible with standard VLSI manufacturing techniques, but it is not as thermally conductive as SiC.

### EXAMPLE

### HEMT

An aspect of this invention comprises the process of fabricating an HEMT as shown in FIG. 5 from a free standing lamina and epitaxial layer and begins with a donor body of an appropriate semiconductor material. An appropriate donor body may be a semiconductor wafer such as silicon carbide of any practical thickness, for example from about 200 to about 1000 microns thick. In alternative embodiments, the donor wafer may be thicker; maximum thickness is limited only by practicalities of wafer handling. Alternatively, polycrystalline or multicrystalline silicon may be used, as may microcrystalline silicon, or wafers or ingots of other semiconductor materials, including germanium, silicon germanium, or III-V or II-VI semiconductor compounds such as GaAs, InP, etc. Other material may be used, such as silicon, LiNbO₃, SrTiO₃, sapphire, and the like. Epitaxial growth may comprise growing heteroepitaxial layers: a buffer layer of GaN, followed by a barrier layer of AlGaN, followed by a capping layer of GaN. A thin nucleation layer of AlN may be grown first (before the GaN buffer layer). The buffer layer may be 0.5-2 μm thick. The combined thickness of the AlGaN and GaN layers may be between 10-30 nm thick.

Ions, preferably hydrogen or a combination of hydrogen and helium, are implanted into body through the top surface of the epitaxial layer to define a cleave plane, as described earlier. The overall depth of the cleave plane is determined by several factors, including implant energy. The depth of the cleave plane can be between about 0.2 and about 100 microns from the first surface, for example between about 0.5 and about 20 or about 50 microns, for example between about 1 and about 10 microns, between about 1 or 2 microns and about 5 or 6 microns, or between about 4 and about 8 microns. Alternatively, the depth of the cleave plane can be between about 5 and about 15 microns, for example about 11 or 12 microns.

Temperature and dosage of ion implantation may be adjusted according to the material to be implanted and the desired depth of the cleave plane, in order to provide a free standing lamina that is substantially free of physical defects. The ion dosage may be any dosage such as between 1.0×10¹⁴ and 1.0×10¹⁸ H/cm². The implant temperature may be any temperature such as greater than 140° C. (e. g., between 150 and 250° C.). The implant conditions may be adjusted based on the crystallographic orientation of the donor body and the energy of the implanted ions. In some embodiments higher implant temperatures may result in more uniform exfoliation.

An HEMT device is formed on exfoliated SiC, with ion implantation after epitaxial growth of GaN. This provides for an economical way to make a high efficiency electronic device. A SiC substrate is provided with a first surface and epitaxial layers are grown on the first surface. The epitaxy step may be performed at high temperatures, e.g., greater than 900° C., such as greater than 1000° C. Hydrogen is implanted through the epitaxial layers into the SiC, again to a depth from 3-30 μm. The transistor may be finished by forming metalized source/drain contacts, annealing them (825° C. for a short time), depositing Si₃N₄ with plasma-enhanced chemical vapor deposition (PECVD), and isolating the devices with a mesa etch or an N⁺ ion implant. A gate may be formed by etching a pattern in the nitride and depositing metal into this pattern. After the epitaxial growth of the semiconductor material, note that no temperature step is greater than 900° C. In some embodiments the finishing steps may occur at temperatures that are less than the exfoliation temperature (˜950° C. for SiC, ˜450° C. for Si, or 600° C. for Ge) so that finishing occurs before exfoliation. In other embodiments the finishing steps may occur after exfoliation and after a metal support is constructed on the lamina/epitaxial layer assembly. The finishing steps may include mesa etching, forming and annealing Ohmic contacts, depositing metal electrodes, depositing passivation and/or antireflective layers.

Exfoliation while contacting to a non bonded support such as a graphite piece, at 600° C. advantageously provides for the application of additional layers after exfoliation to either side of the lamina/epitaxial layer assembly without a debonding step. Next the resulting exfoliated lamina/epitaxial layer assembly may be bonded to a temporary carrier, by bonding the face that was implanted or the reverse face. A metal support may be constructed on the exfoliated device. The support may comprise a seed layer that is deposited and metal that is electroplated (or otherwise constructed) onto the lamina. (i.e., to the cleaved Si face of the lamina). The constructed metal support has a coefficient of thermal expansion that is matched to the lamina up to 600° C. or higher for subsequent passivation deposition or the application of other layers. The temporary carrier may be removed. Completing the transistor fabrication: depositing Si₃N₄ with PECVD, isolating the devices with a mesa etch or an N⁺ ion implant, then forming the gate by etching a pattern in the nitride and depositing metal into this pattern may occur at any step in the process, before or after exfoliation or before or after the construction of the metal support.

### EXAMPLE

### SiC Power Schottky Diode or DMOSFET

A further aspect of this invention comprises the process of fabricating a high-power device, such as a Schottky diode or a DMOSFET, as shown in FIGS. 6 and 7, respectively, from a free standing lamina and epitaxial layer. This process begins with a donor body of an appropriate semiconductor material. An appropriate donor body may be a semiconductor wafer such as silicon carbide of any practical thickness, for example from about 200 to about 1000 microns thick. In alternative embodiments, the donor wafer may be thicker; maximum thickness is limited only by practicalities of wafer handling. This donor may be doped, for example with phosphorus, to a concentration exceeding 3×10¹⁸ atoms/cm³, for example to a concentration of 1×10¹⁹ atoms/cm³. Epitaxial growth may comprise growing a layer of doped SiC. This layer is doped during growth with, for example, phosphorus, with a concentration between 2×10¹⁵ and 2×10¹⁶ atoms/cm³, for example, between 3×10¹⁵ and 6×10¹⁵ atoms/cm³, for example, 4.5×10¹⁵ atoms/cm³. The epitaxial layer of SiC may be doped non-uniformly throughout its thickness. For example, a layer of more heavily doped SiC may be grown first. This more heavily doped layer may be doped with a concentration between 2×10¹⁷ and 2×10¹⁸ atoms/cm³, for example, between 3×10¹⁷ and 6×10¹⁷ atoms/cm³, for example, 4.5×10¹⁷ atoms/cm³. The total thickness of this epitaxial layer may be between 5 and 30 μm, for example between 8 and 16 μm, for example, 12 μm as shown in the embodiment of FIGS. 6 and 7.

After epitaxial growth, further processing may be performed. For example, dopants of the type opposite, or the same, as the dopant type of the epitaxial layer may be diffused into localized areas on the first surface of the epitaxial layer. These diffusions can be formed, for example, by multiple element co-implantation, for example, using Al, C, and/or B, at an elevated temperature, for example, at 550 to 650 C, for example, at 600 C, followed by an activation anneal at, for example, 1500 to 1650 C, for example, 1600 C. If a Schottky diode is being fabricated, these diffusions form junctions, creating a junction-barrier Schottky diode, as shown in FIG. 6. If a DMOSFET is being fabricated, these diffusions form the body, body contact, and source of the device, as shown in FIG. 7. Further, if a power DMOSFET is being fabricated, a gate oxide may be thermally grown at, for example, 1100 to 1200 C, for example, at 1150 C. An in-situ doped polysilicon gate may then be deposited, for example by low-pressure chemical-vapor deposition (LPCVD).

Ions, preferably hydrogen or a combination of hydrogen and helium, are implanted into the donor body through the top surface of the epitaxial layer to define a cleave plane, as described earlier. The overall depth of the cleave plane is determined by several factors, including implant energy. The depth of the cleave plane can be between about 0.2 and about 100 microns from the first surface, for example between about 0.5 and about 20 or about 50 microns, for example between about 1 and about 10 microns, between about 1 or 2 microns and about 5 or 6 microns, or between about 4 and about 8 microns. Alternatively, the depth of the cleave plane can be between about 5 and about 20 microns, for example about 13 to 15 microns.

Temperature and dosage of ion implantation may be adjusted according to the material to be implanted and the desired depth of the cleave plane, in order to provide a free standing lamina that is substantially free of physical defects. The ion dosage may be any dosage such as between 1.0×10¹⁴ and 1.0×10¹⁸ H/cm². The implant temperature may be any temperature such as greater than 140° C. (e. g., between 150 and 250° C.). The implant conditions may be adjusted based on the crystallographic orientation of the donor body and the energy of the implanted ions. In some embodiments higher implant temperatures may result in more uniform exfoliation.

A power Schottky diode or DMOSFET is formed on exfoliated SiC, with ion implantation after epitaxial growth of doped SiC. This provides for an economical way to make a high power electronic device. A SiC substrate is provided with a first surface and epitaxial layers are grown on the first surface. The epitaxy step may be performed at high temperatures, e.g., greater than 1400° C., such as greater than or equal to 1500° C. Hydrogen is implanted through the epitaxial layers into the SiC, again to a depth from 3-30 μm. The device may be finished by first forming a metalized contact on the cleaved surface of the device, by depositing a metal, for example, Ni, and annealing it at a temperature of, for example, greater than 900 C. Alternatively, a layer of amorphous silicon may be deposited on this surface, using techniques such as plasma-enhanced chemical vapor deposition (PECVD), and further depositing a metal, for example Ni, onto the amorphous silicon, and subsequently annealing at temperatures, for example, between 250 and 350 C, for example, 300 C. To fabricate a Schottky diode, a Schottky metal contact may be deposited on the top surface of the epitaxial layer. This metal may be comprised of, for example, Ti, Ni, or Al, and may be deposited by, for example, sputtering. To fabricate a DMOSFET, the polysilicon gate may be patterned using, for example, photolithography. Ohmic contacts may then be formed on the top surface of the epitaxial layer, in a manner similar to that described for the ohmic contact on the rear (cleaved) surface of the device. In some embodiments the finishing steps may occur at temperatures that are less than the exfoliation temperature (˜950° C. for SiC) so that finishing occurs before exfoliation. In other embodiments the finishing steps may occur after exfoliation and after a metal support is constructed on the lamina/epitaxial layer assembly.

Exfoliation while contacting to a non bonded support such as a graphite piece, at 600° C. advantageously provides for the application of additional layers after exfoliation to either side of the lamina/epitaxial layer assembly without a debonding step. The lamina may be annealed, for example at between 1000 and 1200 C, for example at 1150 C, to remove any defects caused by the hydrogen implant. Next the resulting exfoliated lamina/epitaxial layer assembly may be bonded to a temporary carrier, by bonding the face that was implanted or the reverse face. A metal support may be constructed on the exfoliated device. The support may comprise a seed layer that is deposited and metal that is electroplated (or otherwise constructed) onto the lamina (i.e., to the cleaved Si face of the lamina). In some embodiments, the constructed metal support has a coefficient of thermal expansion that is matched to the lamina up to 600° C. or higher for subsequent passivation deposition or the application of other layers. The temporary carrier may be removed. Completing the device fabrication may occur at any step in the process, before or after exfoliation or before or after the construction of the metal support.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention. Furthermore, those of ordinary skill in the art will appreciate that the foregoing description is by way of example only, and is not intended to limit the invention. Thus, it is intended that the present subject matter covers such modifications and variations.

1. A method of forming an electronic device, the method comprising the steps of:
providing a donor body comprising a top surface;
growing an epitaxial layer of a semiconductor material on the top surface;
implanting the top surface of the donor body with an ion dosage to form a cleave plane;
exfoliating a lamina and epitaxial layer assembly from the donor body, wherein the top surface of the donor body becomes a first surface of the lamina, wherein the step of exfoliating the lamina forms a second surface of the lamina, wherein the first surface is opposite the second surface; and
constructing a metal support on the lamina.

2. (canceled)

3. The method of claim 1 wherein the lamina is between 2 and 40 microns thick between the first surface and the second surface.

4. The method of claim 1 wherein the epitaxially grown semiconductor material is selected from the group consisting of GaN, AlGaN, AlN, Ge, Ga(In)As, GaInP, AlGaInP, AlInP, SiC, GaAs, and InGaN.

5. The method of claim 1 wherein the donor body is selected from the group consisting of germanium, gallium arsenide, silicon carbide, silicon and gallium nitride.

6. The method of claim 1 wherein the combined thickness of the lamina and the epitaxial layer assembly is between 2 and 25 microns.

7. The method of claim 1 wherein the step of growing the epitaxial layer of the semiconductor material occurs prior to implanting the top surface of the donor body with an ion dosage.

8. The method of claim 1 wherein constructing the metal support on the lamina comprises constructing the metal support on the second surface of the lamina.

9.-21. (canceled)

22. The method of claim 1 wherein the lamina has a first coefficient of thermal expansion and the metal support has a second coefficient of thermal expansion, and wherein the second coefficient of thermal expansion is within 10% of the first coefficient of thermal expansion between the temperatures of 300 and 600 ° C.

23. The method of claim 1 wherein the lamina has a first coefficient of thermal expansion and the metal support has a second coefficient of thermal expansion, and wherein the first coefficient of thermal expansion is within 10% of the second coefficient of thermal expansion between the temperatures of 500 and 1000 ° C.

24. The method of claim 1 further comprising the step of applying a temporary carrier to the lamina prior to constructing the metal support on the lamina.

25. The method of claim 24 wherein the electronic device is a photovoltaic assembly.

26. The method of claim 24 wherein the electronic device is a light emitting device.

27. The method of claim 26 wherein the metal support further comprises a second layer comprising nickel, iron, cobalt or any combination thereof; and wherein a first seed layer is disposed between the second layer and the lamina.

28. The method of claim 24 wherein the electronic device is a high electron mobility transistor.

29. The method of claim 24 wherein the electronic device is a high-power Schottky diode.

30. The method of claim 24 wherein the electronic device is a high-power diffused metal-oxide-semiconductor field-effect transistor.

31. The method of claim 10 wherein the electronic device is a terahertz optoelectronic device.

32. The method of claim 1 further comprising the step of forming an electronic device comprising the lamina, the epitaxial layer and the metal support; wherein the forming of the electronic device is after the step of constructing the metal support on the lamina.

33. The method of claim 1 further comprising the step of forming an electronic device comprising the lamina and the epitaxially grown semiconductor material; wherein the forming of the electronic device is prior to the step of constructing the metal support on the lamina.

34. The method of claim 33 wherein forming the electronic device comprises the steps of (i) forming metalized contacts on the epitaxially grown semiconductor material and (ii) depositing Si₃N₄ on the epitaxially grown semiconductor material.

35. The method of claim 1 wherein the step of constructing the metal support comprises electroplating
